(19) United States
(12) Patent Application Publication
(10) Pub. No.: US 2013/0057782 A1
(43) Pub. Date: Mar. 7, 2013

(54) TELEVISION RECEIVER AND ELECTRONIC EQUIPMENT

(71) Applicants: Issei Takahashi, Oume-shi (JP); Naoki Tani, Oume-shi (JP)

(72) Inventors: Issei Takahashi, Oume-shi (JP); Naoki Tani, Oume-shi (JP)

(21) Appl. No.: 13/448,795

(22) Filed: Apr. 17, 2012

(30) Foreign Application Priority Data
Sep. 1, 2011 (JP) 2011-191125

(51) Int. Cl. H04N 5/64; H05K 5/00

(52) U.S. Cl. 348/836; 361/679.01; 348/E05.128

(57) ABSTRACT

One embodiment provides a television receiver including: a first casing having a first opening part; a second casing having a second opening part; a board positioned between the first casing and the second casing, the board having a third opening part, the board further having a tubular surrounding part surrounding a periphery of the third opening part and projected toward an internal face of the second casing; a projected part inserted from the internal face of the second casing toward the inside of the surrounding part; a fixed member passing through the first to third opening pars from the first casing side, and fixed at the projected part; and a covering member provided on the first casing, and covering the first opening part.

### CROSS-REFERENCE TO RELATED APPLICATION(S)

This application claims priority from Japanese Patent Application No. 2011-191125 filed on Sep. 1, 2011, the entire contents of which are incorporated herein by reference.

### FIELD

Embodiments described herein relate generally to a television receiver and an electronic equipment.

### BACKGROUND

Printed circuit boards are accommodated within electronic equipments such as an television receiver, etc. These equipments are required to be of thin structure.

### BRIEF DESCRIPTION OF DRAWINGS

A general architecture that implements the various features of the present invention will now be described with reference to the drawings. The drawings and the associated descriptions are provided to illustrate embodiments and not to limit the scope of the present invention.

FIG. 1 illustrates a television receiver according to a first embodiment from front.

FIG. 2 cross-sectionally illustrates the television receiver.

FIG. 3 illustrates a middle frame from front.

FIG. 4 illustrates a note-book type PC according to a second embodiment.

FIGS. 5A to 5F illustrate the note-book type PC from every direction.

FIG. 6 illustrates the internal structure of the note-book type PC.

FIGS. 7A and 7B illustrate a connecting part between first and second body parts.

FIG. 8 enlargedly illustrates the connecting part.

FIG. 9 cross-sectionally illustrates the connecting part.

FIG. 10 illustrates the second body part from front.

FIG. 11 illustrates the internal structure of the second body part.

FIGS. 12A and 12B illustrate the shape and the arrangement of a supporting member from front and back, respectively.

FIG. 13 illustrates the positional relationship between a supporting member and a keyboard.

FIG. 14 illustrates the positional relationship between a supporting member and a battery from back.

FIGS. 15A and 15B cross-sectionally illustrate the battery.

FIG. 16 illustrates the internal structure of the second body part from back.

FIGS. 17A and 17B cross-sectionally illustrate a screw attaching method.

FIGS. 18A to 18C illustrate beam structures.

FIG. 19 illustrates an opening part of the supporting member from front.

### DETAILED DESCRIPTION

One embodiment provides a television receiver including: a first casing having a first opening part; a second casing having a second opening part, and combined with the first casing; a board positioned between the first casing and the second casing, the board having a third opening part communicating with the first opening part and the second opening part in a direction overlapping with the first casing and the second casing, the board further having a tubular surrounding part surrounding a periphery of the third opening part and projected toward an internal face of the second casing; a projected part inserted from the internal face of the second casing toward the inside of the surrounding part; a fixed member passing through the first opening part, the second opening part and the third opening part from the first casing side, and fixed at the projected part; and a covering member provided on the first casing, and covering the first opening part.

Embodiments will be described with reference to the attached drawings

### First Embodiment

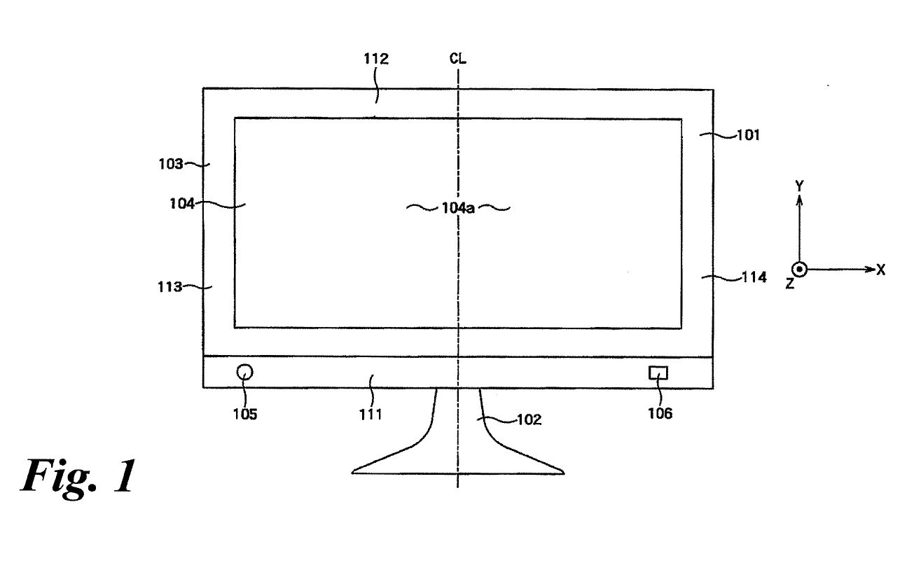

FIG. 1 illustrates a television receiver according to a first embodiment from front.

The television receiver of FIG. 1 includes a body part (display part) 101, and a leg part (stand, supporting part, support part, pedestal part) 102. In this embodiment, upper direction and lower direction are defined with the attitude where the body part 101 is supported by the leg part 102. Right and left directions are defined with the visual point from user. A direction near user is defined as a forward direction, and a direction apart from user is defined as backward direction. In FIG. 1, direction from the left toward the right, direction from lower part toward the upper part, and direction from the backward part toward forward part are respectively represented as X-direction, Y-direction and Z-direction.

The body part 101 includes a casing (covering member, combination member, member, component) 103, a display part (display module, display unit, electronic component) 104 accommodated within the casing 103, and a power button 105 and a remote sensor 106 which are provided on the front surface (front face, display screen side) of the casing 103. The display part 104 includes a display screen 104a exposed to the front surface of the casing 103. ON/OFF operation of the display screen 104a can be performed by depressing operation of the power button 105 and depressing operation of the power button of the remote controller in the state where the fron part of the remote controller is directed toward the remote control sensor 106.

The casing 103 includes first to fourth end parts (side parts, peripheral parts, peripheral edge parts, side parts, walls, faces) 111 to 114. The first end part 111 is an end part (bottom face, bottom wall, supporting face, supporting part, peripheral wall) on which the leg part 102 is attached. The second end part (top plate, upper wall, wall, face, peripheral wall) 112 is positioned on the side opposite to the first end part 111 and extends substantially in a manner parallel to the first end part 111. The third end part (side part, side face, side wall, peripheral wall) 113 is an end part connecting the first end part 111 and the second end part 112, and extends in a direction substantially perpendicular to the first end part 111. The fourth end part (side part, side face, side wall, peripheral wall) 114 is positioned on the side opposite to the third end part 113 and extends in a direction substantially parallel to the third end part 113. Similarly to the third end part 113, the fourth end part 114 connects the first end part 111 and the second end part 112.

The first and second end parts 111, 112 extend in a longer-side direction of the casing 103. The third and fourth end parts 113, 114 extend in a shorter-side direction of the casing 103, and are shorter than the first and second end parts 111, 112.

In the state where the leg part 102 supports the body part 101, the first to the fourth end parts 111 to 114 respectively serve as the lower end part, the upper end part, left end part, and the right end part of the casing 103. In FIG. 1, the first and second end parts 111, 112 are substantially parallel to the X-direction, and the third and fourth end parts 113, 114 are substantially parallel to the Y-direction. In this example, the straight line CL shown in FIG. 1 indicates a center line of the first end part 111 and the second end part 112.

Although the casing 103 includes four end parts 111 to 114 in this embodiment, and the number of end pats of the casing 103 may be three or less, or five or more. The first end part 111 and the second end part 112 may extend in a non-parallel manner. Similarly, the third part 113 and the forth end part 114 may extend in a non-parallel manner.

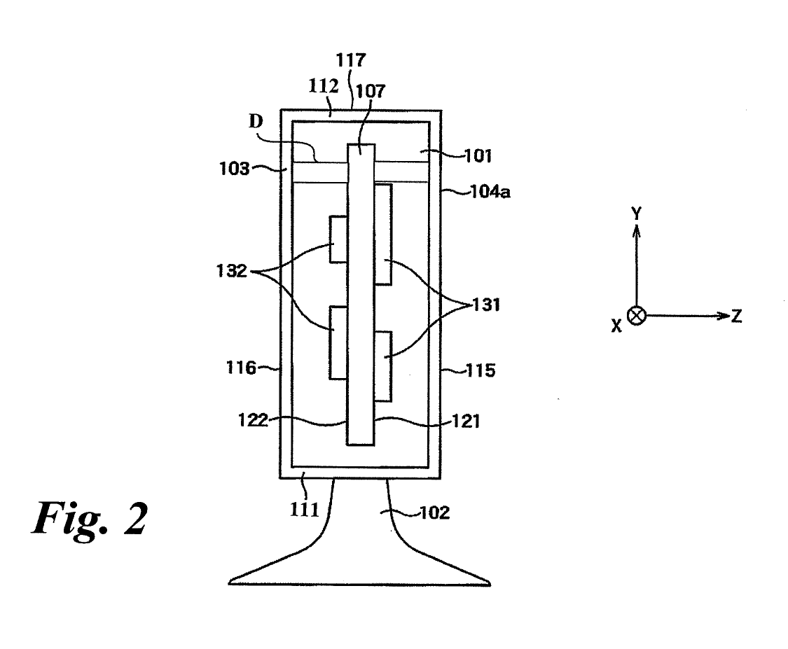

FIG. 2 cross-sectionally illustrates the television receiver according to the first embodiment.

As shown in FIG. 2, the casing 103 includes a front face (a portion of the first casing, first face, first wall, wall, mask) 115, a back face (a portion of the second casing combined with the first casing, second face, second wall, wall, cover) 116, and a peripheral face (a portion of the first casing or the second casing, the third face, the third wall, wall, a portion of the mask or a portion of the cover, a part ranging over the mask and the cover) 117. The front face 115 is a face from which a display screen 104a is exposed. The back face 116 is positioned on the side opposite to the front face 115. The peripheral face 117 is a face connecting the peripheral edge part of the front face 115 and the peripheral edge part of the back face 116.

Although the casing 103 has a face structure including the front face 115, the back face 116 and the peripheral face 117 in this embodiment, the casing 103 may have a structure except for the above-described face structure.

As shown in FIG. 2, the body part 101 further includes a middle frame (a portion of the first casing, casing, supporting part, supporting face, supporting wall, components mounting part, frame intermediate member skeleton member, plate, reinforcing member) 107 accommodated within the casing 103. The middle frame 107 is a supporting member for supporting various components.

The middle frame 107 includes a first supporting face (first face, wall) 121 and a second supporting face (second face, wall) 122. The first supporting face 121 is a face facing the front surface 115 side. The second supporting face 122 is a surface facing the back surface 116 side, and is positioned on the side opposite to the first supporting surface 121.

The body part 101 includes a first electronic component 131 disposed on the first supporting surface 121 of the middle frame 107, and a second electronic component 132 disposed on the second supporting surface 122 of the middle frame 107. An example of these electronic components 131, 132 is a printed circuit board on which semiconductor elements and/or circuit elements are mounted. One surface of the printed circuit board and the supporting face of the middle frame 107 exist at a position where they are proximal (close substantially proximal through an insulator, etc. to each other). Components except for the electronic components 131, 132 may be disposed on the faces, the regions, the parts and the supporting parts of the middle frame 107 such as supporting surfaces 121, 122 of the middle frame 107.

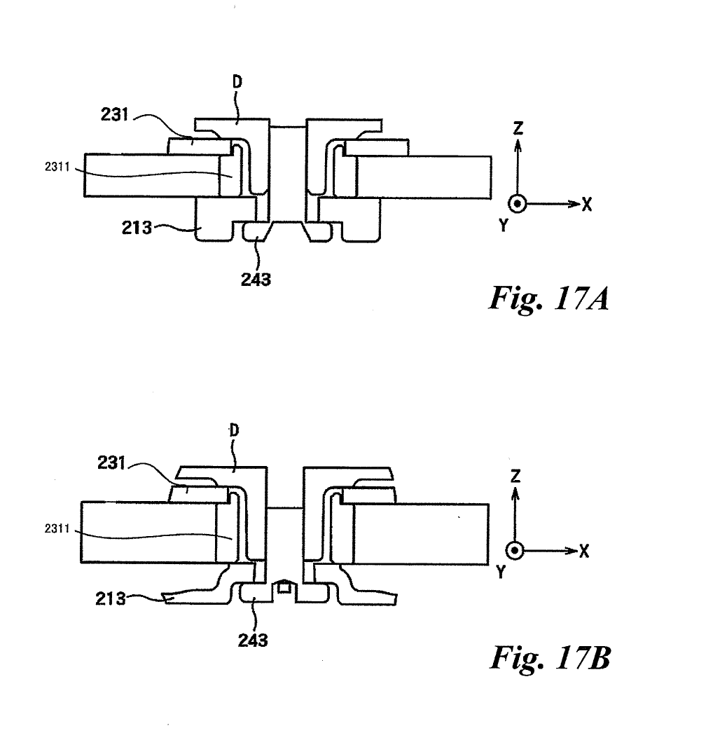

In this embodiment, as described above, one surface of such a printed circuit board is fixed to be close up to the supporting surface of the middle frame 107 serving as the casing. A practical fixing method will be described later with reference to FIGS. 17A and 17B. Employment of fixing structure of this embodiment permits the positions of the casings between which the printed circuit board is put to be close to each other.

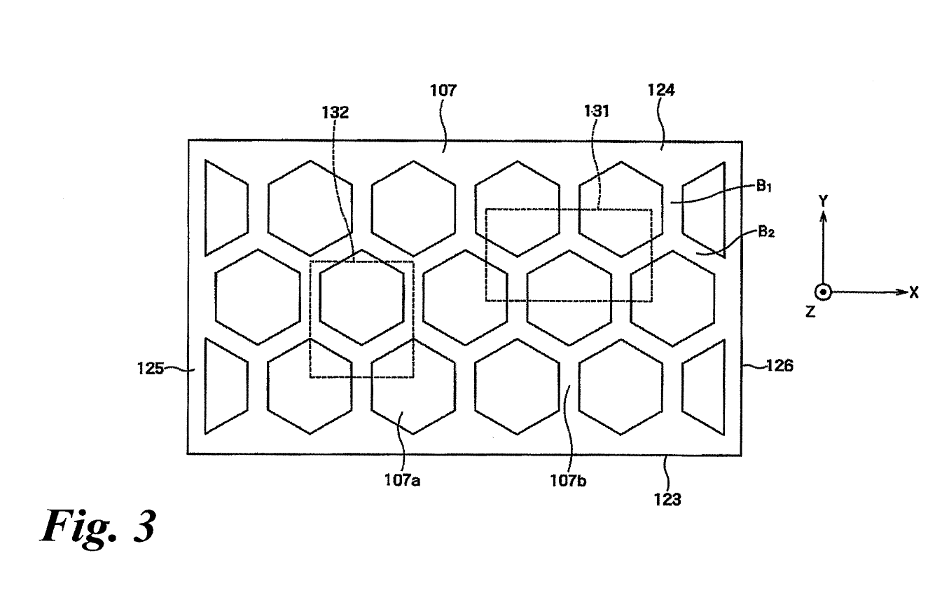

FIG. 3 illustrates the middle frame 107 from front.

As shown in FIG. 3, the middle frame 107 includes first to forth end parts (side parts, peripheral parts, peripheral edge parts, side parts, walls, faces) 123 to 126. The first end part (bottom face, bottom wall, supporting surface, supporting part, peripheral wall) 123 is an end part positioned end side of the leg part 102 side. The second end part (top plate, upper wall, wall, face, peripheral wall) 124 is positioned on the side opposite to the first end part 123, and extends in a manner substantially parallel to the first end part 123. The third end part (side part, side face, side wall, peripheral wall) 125 is an end part connecting the first end part 123 and the second end part 124, and extends in a direction substantially perpendicular to the first end part 123. The fourth end part 126 is positioned on the side opposite to the third end part 125, and extends in a manner substantially parallel to the third end part 125. The fourth end part (side part, side face, side wall, peripheral wall) 126 serves to connect the first end part 123 and the second end part 124 similarly to the third end part 125.

The first and second end parts 123, 124 extend in a longer-side direction of the middle frame 107. The third and fourth end parts 125, 126 extend in a shorter-side direction of the middle frame 107, and are shorter than the first and second end parts 123, 124.

In the case where the leg part 102 supports the body part 101, the first to fourth end parts 123 to 126 respectively serve as the lower end part, the upper end part, the left and part and the right end part of the middle frame 107. In FIG. 3, the first and second end parts 123, 124 are substantially parallel to the X-direction, and the third and fourth end parts 125, 126 are substantially parallel to the Y-direction.

Although the middle frame 107 includes four end parts 123 to 126 in this embodiment, the number of the end parts of the middle frame 107 may be three or less or five or more. The first and second end parts 123 and 124 may extend in a non-parallel manner. Similarly, the third end part 125 and the fourth end part 126 may extend in a non-parallel manner.

As shown in FIG. 3, the middle frame 107 includes plural opening parts 107a penetrated from the first supporting face 121 toward the second supporting face 122, and a beam (wall, support face, supporting plate, supporting region, intermediate part, pillar part, bridging part, reinforcing part) 107b provided between the opening parts 107a. The middle frame 107 is enlighten as a result of the fact that these opening parts 107a are provided.

The middle frame 107 includes an opening part having hexagonal shape as the opening part 107a. As a result, the middle frame 107 has honeycomb-type beam structure. In FIG. 3, a beam 107b of the middle frame 107 includes a first beam part (part, region, extended part, a part ranging thereover) B₁ parallel to third end part 125 (i.e., parallel to the Y-direction), and a second beam part (part, region, extended part, part ranging thereover) B₂ in a manner which is not parallel to the first and third end parts 123 and 125 (i.e., in a non-parallel to the X-direction and the Y-direction). These beam parts B₁ and B₂ constitute a honeycomb-type beam structure.

As described above, the middle frame 107 of this embodiment has the honeycomb-type structure including the first beam part B₁ parallel to the Y-direction, and the second beam part B₂ which is not parallel to the X-direction and the Y-direction. Such honeycomb-type beam structure has the following advantages as compared to the square-type beam structure including the first beam part B₁ parallel to the Y-direction and the second beam part B₂ parallel to the X-direction.

First, the middle frame 107 having the honeycomb-type beam structure indicates higher torsion bend rigidity as compared to a middle frame 107 of the same weight having the square-type beam structure.

Secondly, the middle frame 107 having the honeycomb-type beam structure indicates higher rigidity with respect to pressure from the first and second end parts 123, 124 side, and pressure from the third and forth end parts 125, 126 side as compared to the middle frame 107 of the same weight having the square-type beam structure.

Thirdly, in accordance with the middle frame 107 having the honeycomb-type beam structure, it becomes possible to enlighten the middle frame 107 similarity to the middle frame 107 having the square-type beam structure.

As described above, in accordance with this embodiment, employment of the beam structure can enhance the rigidity of the middle frame 107 while enlightening the middle frame 107. As a result, it is possible to realize enlightening and improvement in rigidity of the television receiver.

In recent years, realization of enlargement and thin structure of the television receivers have been rapidly developed. In general, enlargement of the television receiver would result in heavy weight of the television receiver and realization of thin structure of the television receiver would result in lowering of rigidity of the television receiver. In accordance with this embodiment, employment of the middle frame 107 having the honeycomb-type beam structure can comply with these problems followed by enlargement and thin structure of the television receiver.

The middle frame 107 may have beam structures except for the above-described beam structure, but may have, e.g., a beam structure including the first and second beam structures B₁, B₂ which are not parallel to each other and are not perpendicular to each other. As an example of such beam structure, there may be mentioned a honeycomb-type structure including a first beam part B₁ parallel in the X-direction and a second beam part B₂ which is not parallel to the X-direction and the Y-direction.

Similarly to the above-described beam frame 107b, enlightening and improvement in rigidity as described above may be realized even by providing, at the middle frame 107, a supporting part including a first part B₁ parallel to the Y-direction and a second part B₂ which is not parallel to the X-direction and the Y-direction, an reinforcing part, a convex part, a projected part and/or a thickened part, etc. The supporting part is a part for supporting parts. The reinforcing part is a part for reinforcing the middle frame 107. The convex part is a part having convex shape with respect to the opening part 107a, and the projected part is a part projected into the opening part 107a. Thickened part is a thickened part within the middle frame 107.

As described above, the middle frame 107 of this embodiment has a beam structure including a first beam part B₁ parallel to the first or third end parts 123, 125, and a second beam part B₂ which is not parallel to the first and third end parts 123, 125. Thus, in accordance with this embodiment, employment of the beam structure can enhance rigidity of the middle frame 107 while enlightening the middle frame 107.

This embodiment may be applied to electronic equipments except for the television receiver, e.g., the note-book type PC (Personal Computer). An example of such a note-book type PC will be described in the second embodiment.

### Second Embodiment

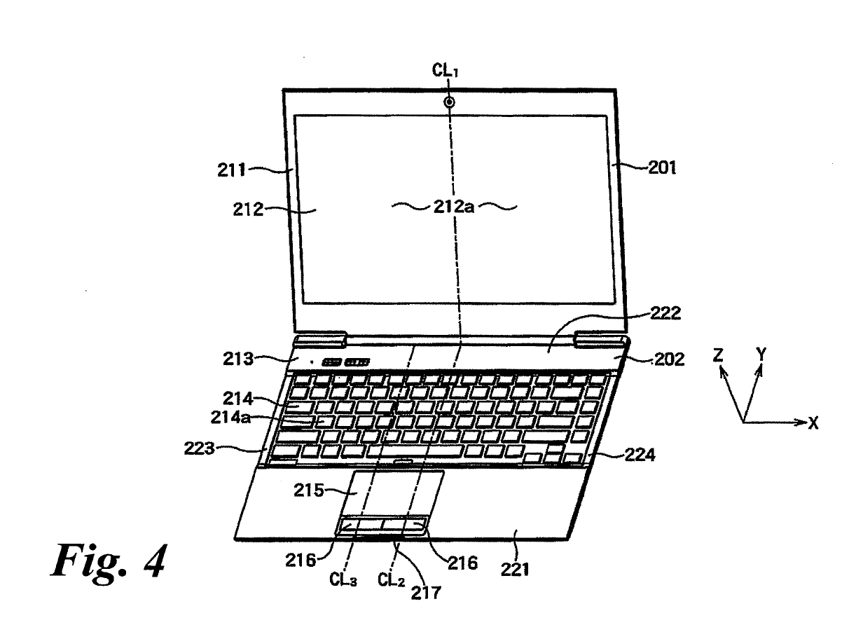

FIG. 4 illustrates the note-book type PC of the second embodiment. The note-book type PC of FIG. 4 may be a PC functioning as a television receiver, or may be a PC which does not function as the television receiver.

The PC of FIG. 4 includes a first body part (first part, first component accommodating part) 201, and a second body part (second part, second component accommodating part) 202.

The first body part 201 includes a first casing (covering member, member, assembly component, component, supporting part, reinforcing part) 211, and a display part (display module, display unit, electronic part, part) 212 accommodated within the first casing 211. The display part 212 includes a display screen 212a exposed to the front face of the first casing 211. A straight line CL₁ shown in FIG. 4 indicates a center line of the first casing 211.

The second body part 202 includes a second casing (cover member, member, assembly component, component, supporting part, reinforcing part) 213, a keyboard (input part, input receiving part, receiving part, operating part, operation region, interface part, input module, unit, component) 214 accommodated within the second casing 213, a pointing device (input part, input receiving part, receiving part, operating part, operation region, interface part, input module, unit, component, face, region where touch sensor functions) 215 provided on the front face of the second casing 213, a click pad (input part, input receiving part, receiving part, operating part, operation region, interface part, input module, unit, component, face, region where touch sensor functions) 216, and a finger hook part (opening part, offset part, concave part, hook part, convex part) 217. The keyboard 214 includes plural keys 214a exposed to the front face of the second casing 213. The straight line CL₂ shown in FIG. 4 indicates a center line of the second casing 213. A straight line CL₃ indicates a boundary line between the right home position and the left home position of the keyboard 214.

In this embodiment, the second body part 202 is provided on the horizontal face. And, left and right directions, upper and lower directions and forward and backward directions of the second body part 202 are defined with the state where the first body part 201 is opened from a part close to user toward a part apart therefrom. In this embodiment, the direction parallel to the horizontal surface and parallel to the straight line connecting the left eye and the right eye of user is defined as “left and right directions”, and the direction perpendicular to this straight line is defined as “upper and lower direction”. The direction perpendicular to the horizontal surface is defined as “forward and backward directions”, a part close to user is defined as forward direction, and a part apart therefrom is defined as “backward direction”. In FIG. 1, directions from the left direction the right direction, direction from the lower direction to the upper direction and the direction from the backward direction toward the forward direction are respectively indicated as X-direction, Y-direction and Z-direction.

The second casing 213 includes first to fourth end parts (end parts, peripheral parts, peripheral edge parts, side parts, walls, faces) 221 to 224. The first end part (end part on the side opposite to hinge, end part in a longer-side direction, side part, peripheral part, peripheral edge part, side part, wall, face) 221 is an end part on which the finger hook part 217 is provided. The second end part (end part on the side of hinge, end part in a longer-side direction, side part, peripheral part, peripheral edge part, side part, wall, face) 222 is an end part at which the connecting part between the first casing 211 and the second casing 213 is provided, and is positioned on the side opposite to the end part 221 and extends substantially in a manner parallel to the first end part 221 or in a manner parallel thereto. The third end part (end part in a shorter-side direction, side part, peripheral part, peripheral edge part, side part, wall, face) 223 is an end part connecting the first end part 221 and the end part 222, and extends in a direction substantially perpendicular to the first end part 221. The forth end part (end part in a shorter-side direction, side part, peripheral part, peripheral edge part, side part, wall, face) 224 is positioned on the side opposite to the third end part 223, and extends in a manner substantially parallel to the third end part. The fourth end part 224 serves to connect the first end part 221 and the second end part 222 similarly to the third end part 223.

The first and second end parts 221 and 222 extend in a longer-side direction of the second casing 213. The third and fourth end parts 223, 224 extend in a shorter-side direction of the second casing 213, and are shorter than the first and second end parts 221 and 222.

In the case where the second body part 202 is provided on the horizontal plane surface, and the first body part 201 is opened from a part close to user toward a part apart therefrom, the first to fourth end parts 221 to 224 respectively serve as the lower end part, the upper end part, the left end part and the right end part of the second casing 213. In FIG. 4, the first and second end parts 221 and 222 are substantially in a manner parallel to the X-direction, and the third and fourth end parts 223, 224 are substantially parallel to the Y-direction. In this example, the straight line CL₂ shown in FIG. 4 indicates a center line of the first end part 221 and the second end part 222.

Although the second casing 213 includes s four end parts 221 to 224 in this embodiment, the number of end parts of the second casings 213 may be three or less, or is five or more. The first end part 221 and the second end part 222 may extend in a non-parallel manner. Similarly, the third end part 223 and the fourth end part 224 may extend in a non-parallel manner.

In this embodiment, the boundary line CL₃ of the home position is located on the side of the third end part 223 relative to the center line CL₂. For this reason, the pointing device 215 is disposed in such a manner that the center of gravity is positioned on the side of the third end part 223 relative to the center line CL₂. The boundary line between the left and right click pads 216 is positioned on the side of the third end part 223 relative to the center line CL₂. Furthermore, the finger hook part 217 is provided in such a manner that the center point of the left end thereof and the right end thereof is positioned on the side of the third end part 223 relative to the center line CL₂. The finger hook part 217 is a hollow part used when user hooks finger in using the keyboard 214.

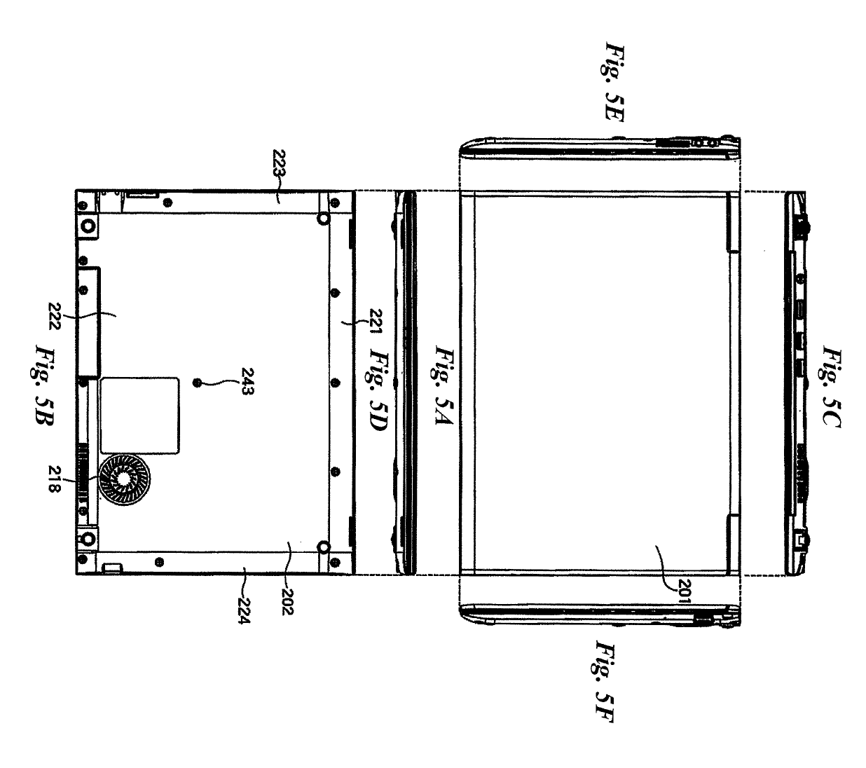

FIGS. 5A to 5F illustrate the note-book type PC of the second embodiment, from every direction.

FIG. 5A is a front view of the PC of this embodiment. In FIG. 5A, the back face of the first body part 201 is shown. FIG. 5B is a back view of the PC of this embodiment. In FIG. 5B, the back face of the second body part 202 is shown. FIG. 5C, FIG. 5D, FIG. 5E and FIG. 5F are respectively the top view, the bottom view, the left side view and the right side view of the PC of this embodiment.

Reference numeral 218 shown in FIG. 5B indicates a fan accommodated within the second casing 213. The fan 218 is disposed, as shown in FIG. 5B, at the second end part 222, and ventilation holes of the fan 218 are provided at the back face of the second casing 213.

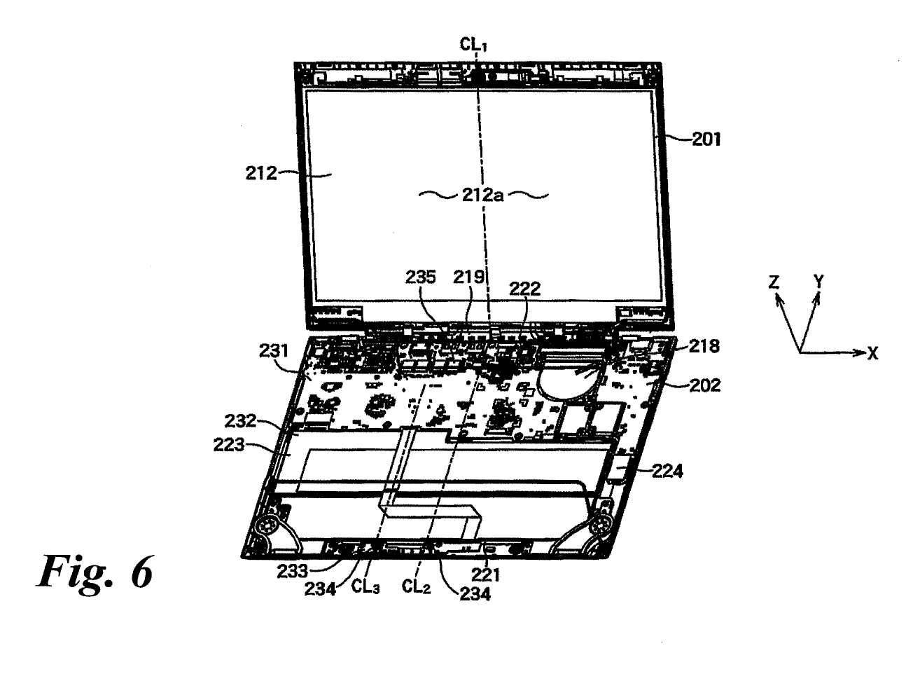

FIG. 6 illustrates the internal structure of the note-book type PC of the second embodiment.

As shown in FIG. 6, within the second casing 213, there are accommodated main printed circuit boards (printed circuit boards, circuit boards, boards, electronic components, components, modules) 231, a battery (battery, power supply part, unit, charging part, components, module) 232 and a circuit printed board 233 for click button 234.

The main printed circuit board 231 is a printed circuit board on which semiconductor elements and/or circuit elements such as CPU (Central Processing Unit) 235, etc. are mounted. The printed main circuit board 231 is disposed at the second part 222. In this example, since the fan 218 is used for cooling the semiconductor elements and/or the circuit elements of the CPU 235, etc., it is disposed at the second part 222 along with the main printed circuit board 231.

The battery 232 is disposed at the first end part 221 with it being put between the first end part 221 and the circuit board 233 for the click button 234. In this embodiment, since the main printed circuit board 231 is disposed within a space on the side of the second end 222, the battery 232 is disposed within a space on the remaining side of the first end part 221.

The circuit board 233 is a printed circuit board on which the click button 234 is mounted. The circuit board 233 is disposed at the first end part 221. In concrete terms, the circuit board 233 is disposed at a position where the click pad 216 and the click button 234 overlap with each other when viewed from the Z-direction.

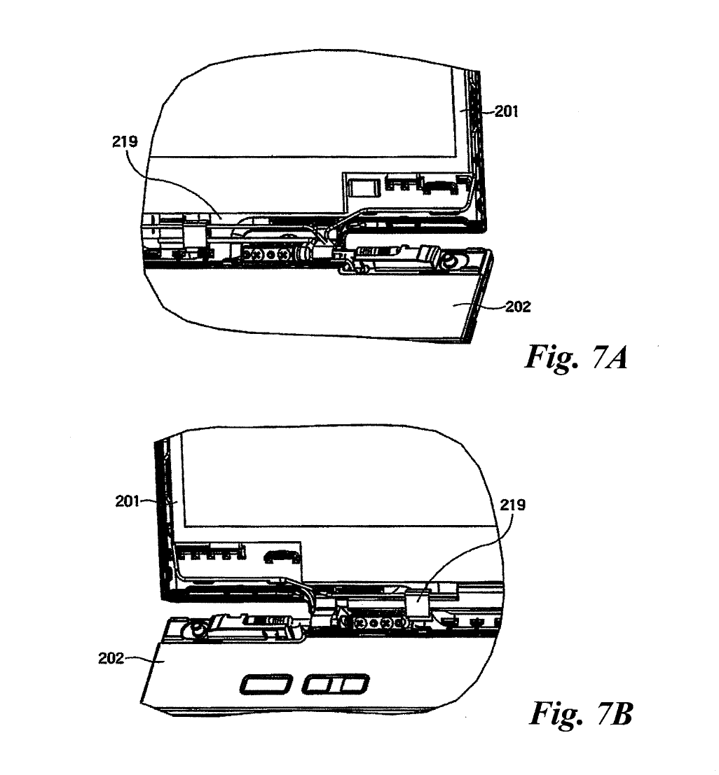

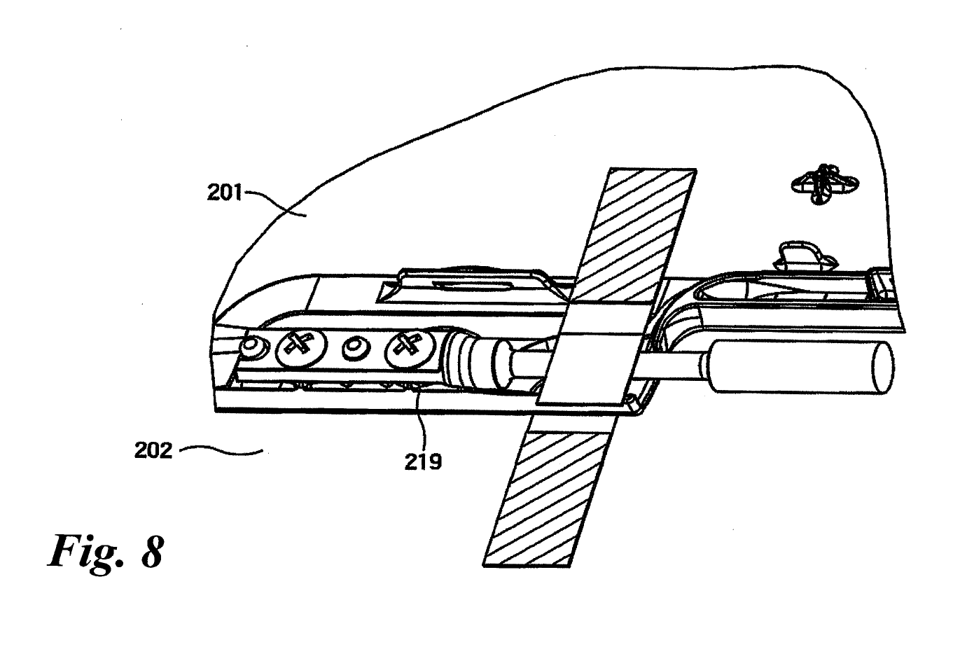

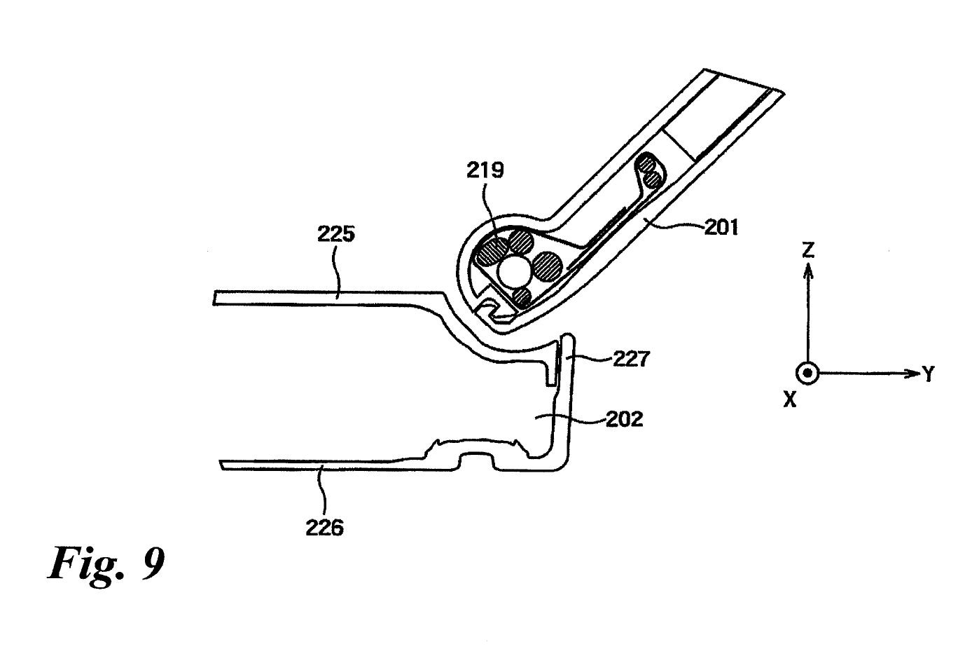

Reference numeral 219 denotes a connecting part of the first body part 201 and the second body part 202. The detail of the connecting part 219 is shown in FIGS. 7A to 9. FIGS. 7A and 7B illustrate the connecting part (hinge part, hinge mechanism, connecting part) 219. FIG. 7A shows a part on the side of the fourth end part 224 of the connecting part 219, and FIG. 7B shows a part on the side of the third end part 223 of the connecting part 219. FIG. 8 enlargedly illustrates the connecting part 219. And, FIG. 9 cross-sectionally illustrates the connecting part 219. In this embodiment, the first body part (first casing) 201 and the second body part (second casing) 202 are connected by means of such a connecting part 219.

As shown in FIG. 9, the second casing 213 includes a front surface (first face, wall, upper face, upper wall, first case, first component) 225, a back face (second face, wall, lower face, bottom wall, second case, second component) 226, and a peripheral face (third face, peripheral wall, side wall, wall, face, region, side part, standing wall) 227. The front face 225 is a face from which the keyboard 214 is exposed. The back face 226 is positioned on the side opposite to the front face 225. The peripheral face 227 is a face connecting the peripheral edge part of the front face 225 and the peripheral edge part of the back face 226. The front face 225 includes, as shown in FIG. 9, a hollow part into which the connecting part 219 is inserted.

Although the second casing 213 of this embodiment has a face structure including the front face 225, the back face 226 and the peripheral face 227, the second casing 213 may have face structures except for the above.

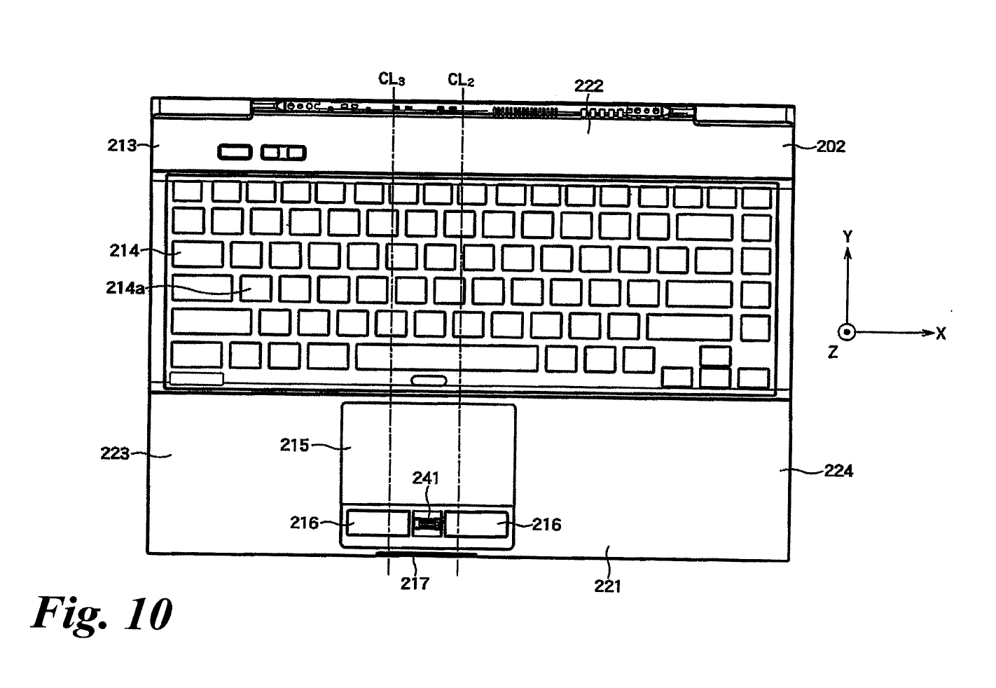

FIG. 10 illustrates the second body part 202 from front.

A fingerprint authentication device 241 of which illustration is omitted for the sake of convenience in FIG. 4 is shown in FIG. 10. The finger authentication device 241 is disposed on the front face of the second casing 213. In particular, the finger authentication device 241 is disposed between the first end part 221 and the mouse pad 216 thereat.

As described above, in this embodiment, the boundary line CL₃ of the home position is located on the side of the third end part 223 relative to the center tine CL₂.

For this reason, the finger authentication device 241 is disposed in such a manner that center of the gravity is positioned toward the third end part 223 side relative to the center line CL₂.

### (1) The Detail of the Supporting Member 242

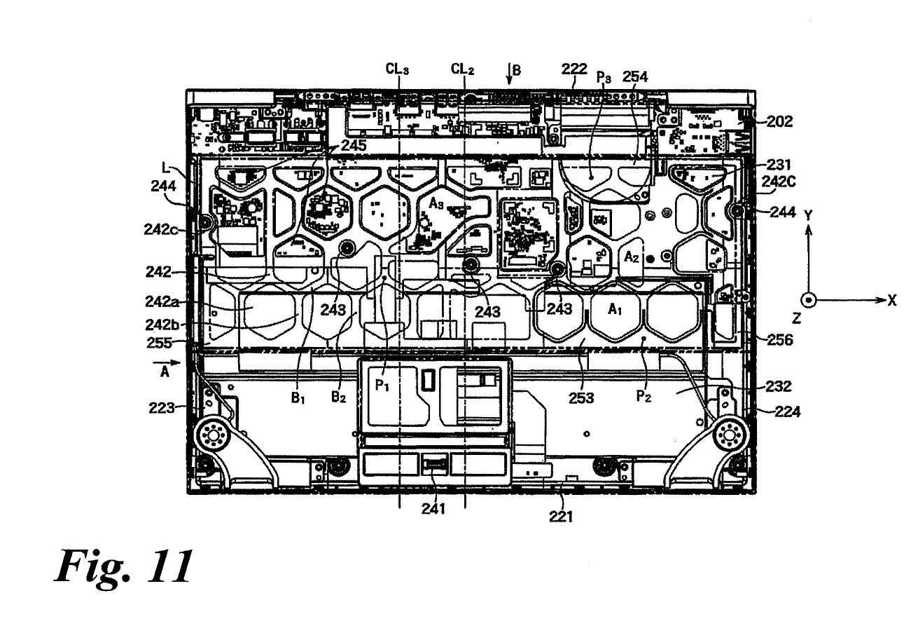

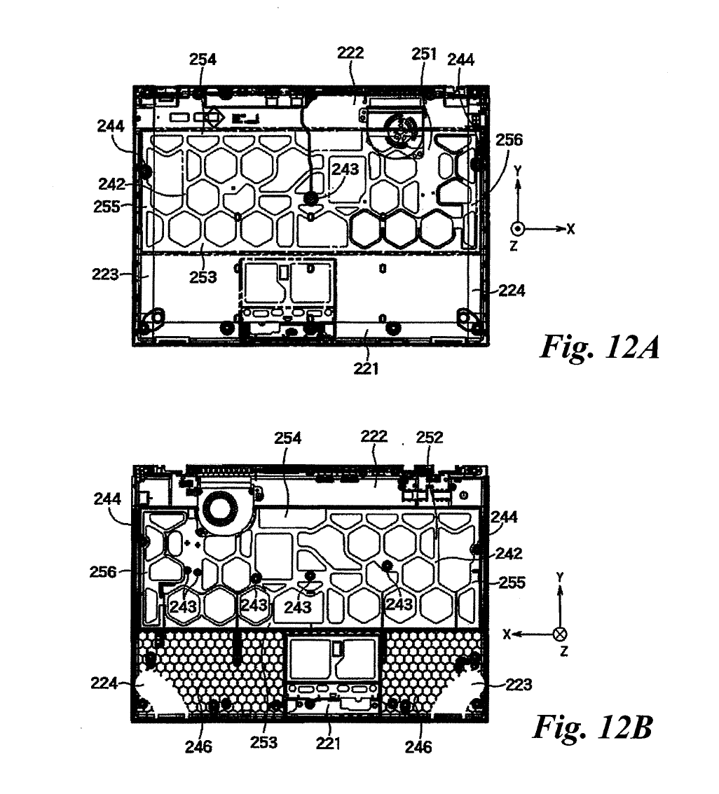

The detail of the supporting member 242 will be described with reference to FIGS. 11 to 12B.

As shown in FIG. 11, the second body part 202 includes a supporting member 242 accommodated within the second casing 213. The supporting member 242 is used for supporting various components within the second casing 213.

The supporting member 242 includes first to fourth end parts 253 to 256. The first end part 253 is an end part positioned on the side of the first end part 221 of the second casing 213. The second end part 254 is positioned on the side opposite to the first end part 253, and extends in a manner substantially parallel to the first end part 253. The third end part 255 is an end part connecting the first end part 253 and the second end part 254, and extends in a direction substantially perpendicular to the first end part 253. The fourth end part 256 is positioned on the side opposite to the third end part 255, and extends in a manner substantially parallel to the third end part 255. The fourth end part 256 serves to connect the first end part 253 and the second end part 254 similarly to the third end part 255.

The first and second end parts 253, 254 extend in a longer-side direction of the supporting member 242. The third and fourth end parts 255, 256 extend in a shorter-side direction of the supporting member 242, and are shorter than the first and second end parts 253, 254.

In the state where the second body part 202 is provided on the horizontal plane surface and the first body part 201 is opened from a part close to user toward a part apart therefrom, the first to fourth end parts 253 to 256 respectively serve as the lower end part, the upper end part, the left end part and the right end part of the supporting member 242. In FIG. 11, the first and the second end parts 253, 254 are substantially parallel to the X-direction, and the third and fourth end parts 255, 256 are substantially parallel to the Y-direction.

Although the supporting member (support, pedestal part, supporting part, supporting face, supporting wall) 242 of this embodiment includes four end parts 253 to 256, the number of end parts of the supporting member 242 may be three or less or five or more. The first end part 253 and the second end part 254 may extend in a non-parallel manner. Similarly, the third end part 255 and the fourth end part 256 may extend in a non-parallel manner.

As shown in FIGS. 12A and 12B, the supporting member 242 includes a first supporting surface (first face, region, part) 251, and a second supporting face (second face, region, part) 252. FIGS. 12A and 12B are a front view and a back view, respectively, showing the shape and the arrangement of the supporting member 242. The first supporting face 251 is a face facing the front face 225 side of the second casing 213. The second supporting face 252 is a face directed toward the back face 226 side of the second casing 213, and is positioned on the side opposite to the first supporting face 251. In this example, reference numeral 246 shown in FIGS. 12A and 12B indicates a rib (projected part, supporting wall, projection, standing wall) of the honeycomb-type structure disposed at a palm rest part (wall, face, region on the side opposite to hinged display relative to the keyboard) of the body part 202.

The supporting member 242 will be described by with reference to FIG. 11.

The supporting member 242 includes plural opening parts 242a penetrated from the first supporting face 251 to the second supporting face 252, a beam (wall, supporting face, supporting plate, supporting region, intermediate part, pillar part, bridging part) 242b provided between the opening parts 242a, and a recessed part (opening part, standing wall, offset part) 242c provided at the first to fourth end parts 253 to 256. The supporting member 242 is enlightened as the result of the fact that these opening parts 242a are provided.

The supporting member 242 includes a hexagonal opening part as an opening part 242a. As a result, the supporting member 242 has a honeycomb-type beam structure. In FIG. 11, the beam (wall, supporting face, supporting plate, supporting region, intermediate part, pillar part, bridging part) 242b of the supporting member 242 includes a first beam part (part, region, extended part, part ranging thereover) B₁ parallel to the third end part 255 (i.e., parallel to the Y-direction), and a second beam part (part, region, extended part, part ranging thereover) B₂ which is not parallel to the first and third beam parts 253, 255 (i.e., which is not parallel to the X-direction and the Y-direction). These beam parts B₁, B₂ constitute the honeycomb-type beam structure.

In this example, the supporting member 242 includes, as second opening part 242a, in addition to the first opening part A₁ having a hexagonal shape, a second opening part A₁ having a shape obtained by cutting hexagonal shape by straight line, and a third opening part A₃ having a shape which does not correspond to the first and second opening parts A₁, A₂.

The positional relationship of the supporting member 242, the main circuit board 231, the battery 232 and the key board 214 will be described with reference to FIG. 11.

The main circuit board 231 is disposed on the side of the second supporting surface 252 of the supporting member 242 within the second casing 213. The main circuit board 231 is disposed at a position partially overlapping with the supporting member 242 in a direction of the first supporting face 251, i.e., when viewed from the X-direction, and is supported by the supporting member 242. The main circuit board 231 and the supporting member 242 are fixed to the second casing 213 by means of screws (fixing metal fittings, coupling members, components, fixing parts, supporting components, members, screws) 243, 244.

Reference numeral 243 indicates a screw penetrated through the supporting member 242. Reference numeral 244 indicates a screw inserted into the recessed part 242c of the supporting member 242. The main circuit board 231 and the supporting member 242 are securely fixed to the second casing 213 by means of these screws 243, 243 attached at the central part and the end part of the supporting member 242.

Reference numeral P₁ shown in FIG. 11 indicates a contact of the single first beam part B₁ and two second beam parts B₂. The strength of the beam 242b at the contact P₁ is higher than the strength of the beam 242b at any other part. In this embodiment, the screws 243 are attached to a position displaced from the contact P₁. This is because each contact P₁ is mainly utilized in this embodiment as positions where respective keys 214a are provided.

Reference numeral 245 indicates circuit components on the main circuit board 231. In order to avoid pressure from the supporting member 242, these circuit components 245 are mainly disposed at a position overlapping with the opening part 242a (a position which does not overlap with the beam part). The third opening part A₃ is utilized, for example, in order to accommodate the circuit component 245 which is not accommodated within the first and second opening parts A₁, A₂.

The battery 232 is disposed on the side of the second supporting face 252 of the supporting member 242 within the second casing 213. The battery 232 is disposed at a position partially overlapping with the supporting member 242 in a direction of the first supporting face 251, i.e., when viewed from the Z-direction. Such an arrangement can advantageously transmit pressure from the supporting member 242 toward the bottom wall of the casing through the battery 232 when keys of the keyboard 242 are depressed.

An encompassing line L shown in FIG. 11 indicates a contour line of the keyboard 214. As described above, in this embodiment, the contour line L of the keyboard 214 is approximately in correspondence with the contour line of the supporting member 242. The keyboard 214 is disposed on the side of the first supporting face 251 of the supporting member 242 within the second casing 213, and is supported by the supporting member 242.

In this embodiment, the CPU 235 (see FIG. 6) on the main circuit board 231 is disposed at positions overlapping with the contour lines of the keyboard 214 and the supporting member 242 when viewed from the Z-direction. In particular, the CPU 235 is disposed at a position overlapping with the second end part 254 of the supporting member 242. Such an arrangement is adapted so that the position of the CPU 235 is apart from the keyboard 214 and/or the palm rest part with which hand of user comes into contact thus to advantageously prevent heat of the CPU 235 from being transmitted to hand of user. The fan 218 can be advantageously disposed at the second end part 222 of the second casing 213 away from user.

The further detail of the positional relationship of the supporting member 242, the main circuit board 231, the battery 232 and the keyboard 214 will be described later in more detail.

A method of fabricating the supporting member 242 will be described with reference to FIG. 11.

In this embodiment, the supporting member 242 is fabricated by, e.g., metal mold. In this instance, in this embodiment, molten metal is caused to flow in a direction indicated by arrow B. This is because since the third end part 255 of the supporting member 242 is shorter than the first end part 253, when molten metal is caused to flow in the direction indicated by the arrow B, a distance required for causing molten metal to flow can be shorter as compared to the case where molten metal is caused to flow in a direction indicated by arrow A thus to permit suppression of lowering of the temperature of molten metal, and to permit shortening of manufacturing time.

In this embodiment, design is made such that the first beam part B₁ is not parallel to the first end part 253, but is parallel to the third end part 255. This is because in the case where molten metal is caused to flow in the direction indicated by B, the molten metal is apt to flow. Thus, in accordance with this embodiment, design is made such that the first beam part B₁ is parallel to the third end part 255, thus facilitating the fabrication of the supporting member 242 by metal mold.

### (2) Advantages/Effects of the Supporting Member 242 of the Second Embodiment

The effects/advantages of the supporting member 242 of the second embodiment will be described with reference to FIG. 11.

As described above, the supporting member 242 of this embodiment has a honeycomb-type beam structure including a first beam part B₁ parallel to the Y-direction, and a second beam part B₂ which is not parallel to the X-direction and the Y-direction. Such honeycomb-type beam structure has the following advantages/effects as compared to the square-type beam structure including a first beam part B₁ parallel to the Y-direction and a second beam part B₂ parallel to the X-direction.

First, the supporting member 242 having a honeycomb-type beam structure indicates higher torsional rigidity as compared to the supporting member 242 of the same weight having a square-type beam structure.

Secondly, the supporting member 242 having the honeycomb-type beam structure indicates high rigidity with respect to pressure from the first and second end parts 253, 254 side and pressure from the third and fourth end parts 255, 256 side as compared to the supporting member 242 of the same weight having the square-type beam structure.

Thirdly, in accordance with the supporting member 242 having the honeycomb-type beam structure, it becomes possible to enlighten the supporting member 242 similarly to the supporting member 242 having the square-type beam structure. According to this embodiment, it becomes possible to enhance the rigidity of the supporting member 242 while enlightening the supporting member 242 by the beam structure. As a result, enlightening and improvement in the rigidity of the note-book type PC can be realized.

In recent years, enlightening and thin structure of the note-book type PC are developed so that there are increased cases where user may carry such note-book type PC to use it. When such enlightening and thin structure as described above are further developed, it is expected that there may be increased cases where user may carry PC by one hand. In this case, if torsional rigidity of PC is lower, there is the possibility that PC may be deformed when user carries it by one hand.

However, in accordance with this embodiment, since torsional rigidity of the supporting member 242 is increased, it becomes possible to comply with these problems followed by enlightening and thin structure of PC. In accordance with this embodiment, such improvement in the rigidity can be realized while avoiding heavy weight of the supporting member 242.

### (3) Arrangement of the Main Circuit Board 231, the Battery 232 and the Keyboard 214

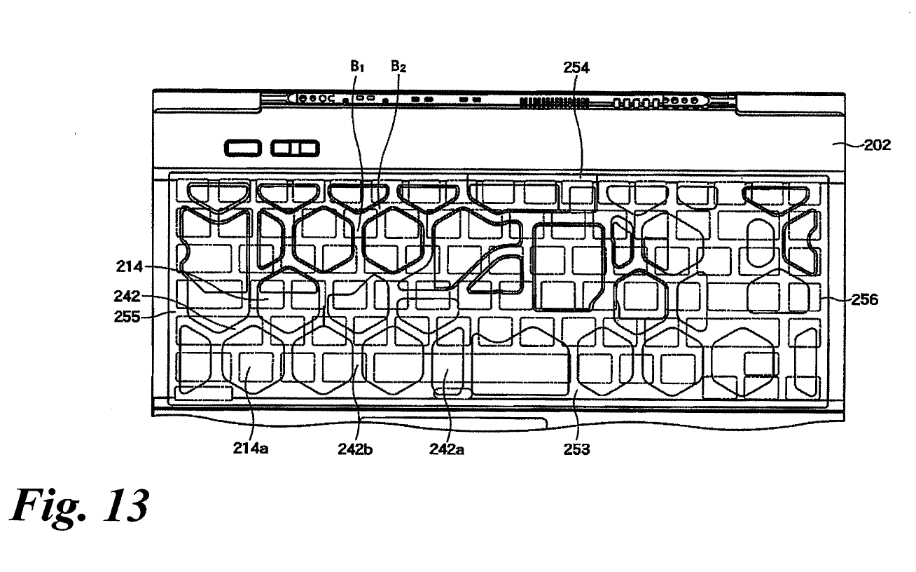

The positional relationship of the supporting member 242, the main circuit board 231, the battery 232 and the keyboard 214 will be described in detail with reference to FIGS. 13 to 17B.

FIG. 13 illustrates the positional relationship between the supporting member 242 and the keyboard 214 from front.

In this embodiment, as shown in FIG. 13, keys 214a of the keyboard 214 are disposed at positions substantially overlapping with the beam 242b.

Such an arrangement can advantageously receive pressure at the time of depressing the key 214a by means of the beam 242b. Such arrangement can be realized by adjusting size and position of the opening part 242a at the time of design.

It is desirable in this embodiment that as many as possible number of keys 214a are disposed at positions overlapping with the point P₁ between the first beam part B₁ and the second beam part B₂. This is because the strength of the 242b at the point P₁ is higher than the strength of the beam part 242b at any other part.

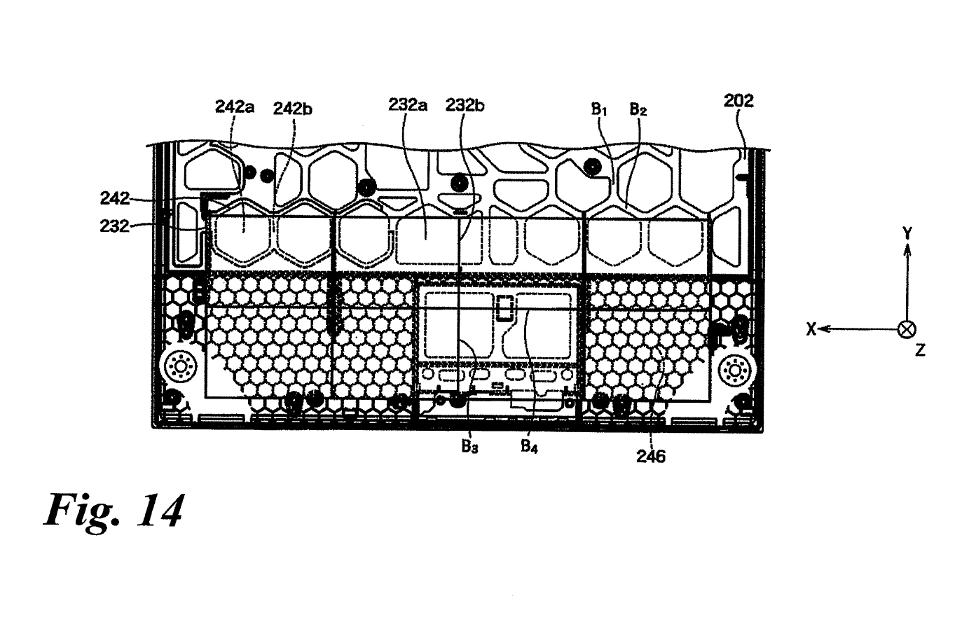

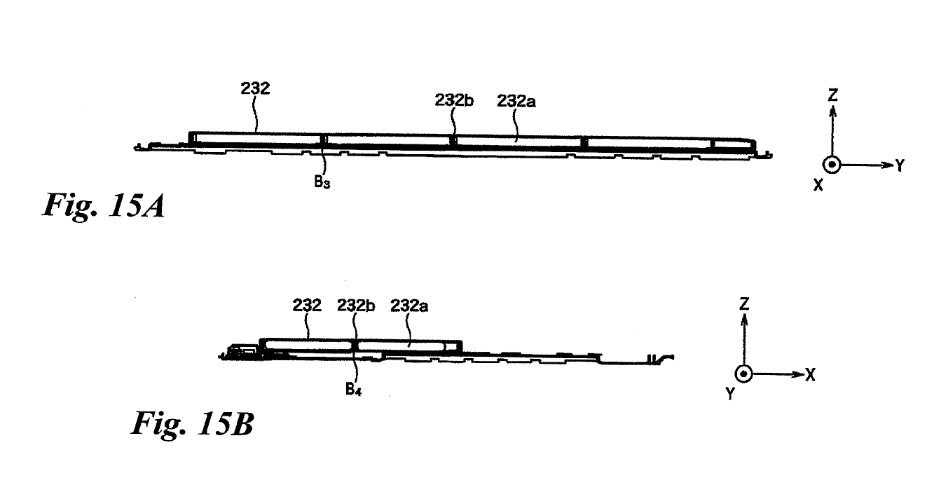

FIG. 14 illustrates the positional relationship between the supporting member 242 and the battery 232 from back. FIGS. 15A and 15B cross-sectionally illustrate the battery 232. FIG. 15A is taken along the Y-direction, and FIG. 15B is taken along the X-direction.

As shown in FIG. 14, the battery 232 includes plural cells 232a, and a beam 232b provided between the cells 232a. The beam 232b of the battery 232 includes a third beam part B₃ parallel to first beam part B₁, and a fourth beam part B₄ which is not parallel to the first beam part B₁. In concrete terms, the third beam part B₃ is disposed in a manner parallel to the Y-direction, and the fourth beam part B₄ is disposed in a manner parallel to the X-direction.

In this embodiment, a partial third beam part B₃ is disposed at a position overlapping with the first beam part B₁ in a direction of the first supporting surface 251, i.e., when viewed from the Z-direction. Such an arrangement can advantageously prevent load from the supporting member 242 from being applied to the cells 232a.

In this example, as shown in FIG. 14, the battery 232 is positioned at a position overlapping with a rib 246 of the honeycomb-type beam structure projected toward the battery 232. Such rib 246 can advantageously also reduce load applied to the battery 232.

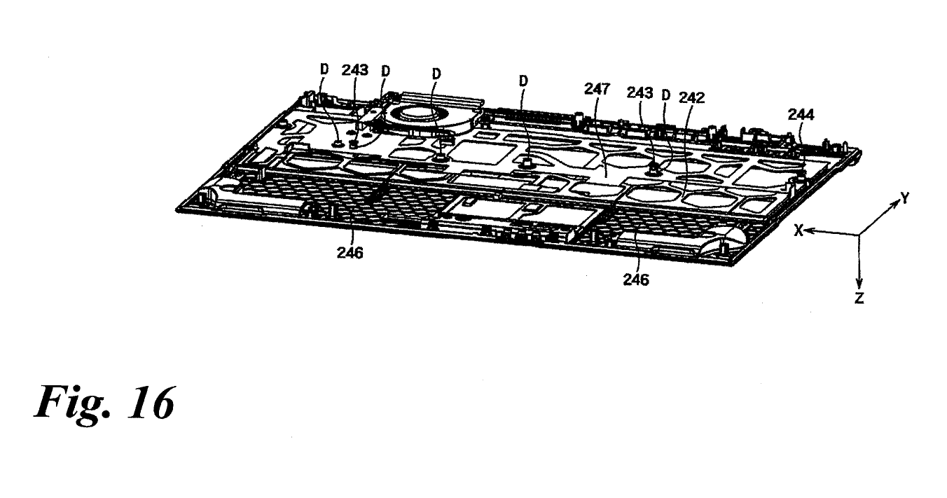

FIG. 16 illustrates the internal structure of the second body part 202 from back.

In FIG. 16, there are shown a supporting member 242, and an insulating film (insulator, intervening part, sheet, intermediate member) 247 disposed on the side of the second supporting surface 252 of the supporting member 242. The insulating film 247 is disposed between the supporting member 242 and the main circuit board 231 thus to prevent the supporting member 242 and the main circuit board 231 from directly coming into contact with each other, and from electrically being in contact with each other. The insulating film 247 may be replaced by insulating members except for the film.

As shown in FIG. 16, the supporting member 242 includes plural projected parts (bosses, fixed parts, projected parts) D projected toward the second supporting face 252 side. The convex part D includes holes (opening parts, fixed parts) into which the screws 243 are inserted. The projected part D and holes of the projected part D include substantially cylindrical shape as shown in FIG. 16.

FIGS. 17A and 17B cross-sectionally illustrate a screw attaching method.

As shown in FIGS. 17A and 17B, the main circuit board 231 includes holes (opening parts, penetration holes, through-parts, cutting parts) adapted so that screws 243 are inserted, and a tubular parts (studs, spacing member, cylindrical parts) 2311 surrounding the peripheries of the opening parts and projected from the main circuit board 231 surface toward one direction. This part 2311 serves to allow the second casing 213 and the board to be separate from each other. This part 2311 has substantially the same projection height as that of the projected part D. The part 2311 is made of metal, and electrically conducts with the conductor-coated inner surface of the casing, and the main circuit board 231 is connected to the ground. In this example, each hole of the main circuit board 231 has a size larger than that of the plane surface shape of the projected part D. Thus, the projected part D is inserted into each hole of the main circuit board.

The height of the projected part D is set in such a manner that it approximately becomes equal to the thickness of the main circuit board 231 and that of the part 2311 (slightly lower than such thickness thereof) (when casings are fastened by means of screws, there results a configuration in which those casings are in contact with the main circuit board 231 and the part 2311). Thus, as shown in FIGS. 17A and 17B, the front end part of the projected part D is substantially positioned in the vicinity of the board surface of the second casing 213 side of the main circuit board 231.

On the other hand, the second casing 213 includes, at the periphery of each insertion hole of the screws 243, shallow hollow parts (recessed parts, opening parts) for accommodating head parts (projected parts, extruded parts, bevel parts, supporting parts, hook parts) of the screws 243. Each screw 243 is inserted from holes of the second casing 213 toward each hole of the projected part D. In this way, the supporting member 242 and the main circuit board 231 are fixed to the second casing 213. An example of such screw 243 is shown in FIG. 5B, for example.

In accordance with the screw attaching method of FIGS. 17A and 17B, it becomes possible to reduce the distance between the second casing 213 and the supporting member 242 as compared to the structure in which the second casing 213 and the supporting member 242 are commonly fastened with the main circuit board 231 being put therebetween. In concrete terms, it becomes possible to reduce the thickness of the main circuit board 231 to a degree of thickness thereof. Thus, in accordance with this method, it becomes possible to hasten realization of thin structure of an equipment in which the circuit board of the note-book type PC or the television receiver which has been described as the first embodiment, etc. is accommodated.

In this embodiment, upper and lower casings are screw-connected on the inside of studs (parts) 2311 attached at the board (main circuit board 231) penetration holes. The main circuit board 231 is fixed with the stud 2311 being clamped by the upper and lower casings which have been screw-connected. The upper and lower casings, the stud and the main circuit board 231 can be connected to the ground GND. In the electronic equipment of this embodiment, the same structure may be applied not only to the fixed structure of the board and the casing, but also to common fastened part between the main circuit board 231 and the battery. In concrete terms, the periphery of the screw hole of the battery is cylindrically projected in a manner similar to the part 2311, and the projected part D is passed therethrough. Such a configuration may contribute to realization of thin structure of the entire casing.

In this embodiment, the stud 2311 serving as the part is projected only toward one side of the board. Employment of such configuration permits one surface of the main circuit board to substantially become proximal to the casing. However, this embodiment is not limited to such configuration, but may be adapted to adjust an amount of each stud projection from the board both surfaces in correspondence with the projection height of each component mounted on the board surface.

The stud 2311 is bonded to the main circuit board 231 by using solder to thereby secure electrical conduction with the main circuit board 231 thus to also contribute to improvement in the strength in the main circuit board 231. In this embodiment, as shown in FIGS. 17A and 17B, a clearance is provided between the stud 2311 and the upper casing (between the stud inner peripheral face and the peripheral face of the projected part D), thereby relaxing an impact applied to PCB from a direction perpendicular to the screw axis direction.

Since one end of each stud 2311 is covered by other parts (keyboard, decorative layer and other surface attachment members of which illustrations are omitted, etc.) on the upper face side of the casing (keyboard side), it is not conspicuous from a viewpoint of device.

### (4) The Detail of the Opening Part 242a of the Supporting Member 242

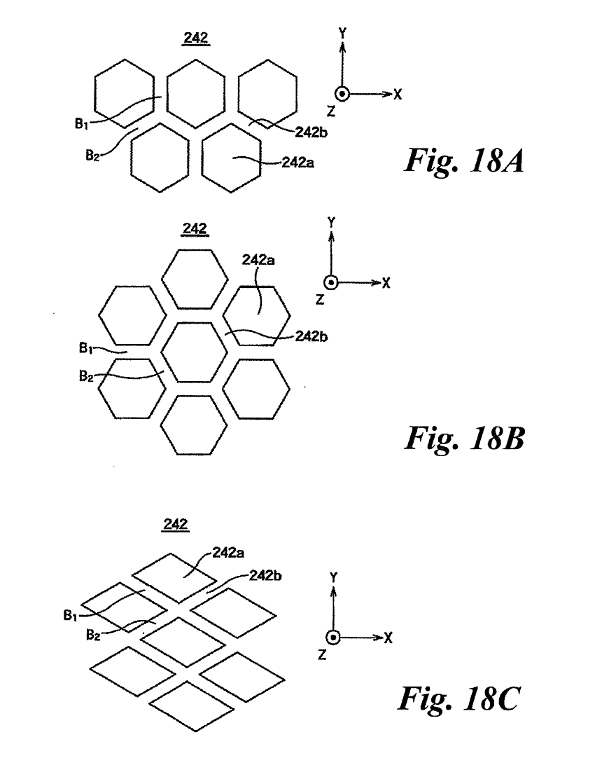

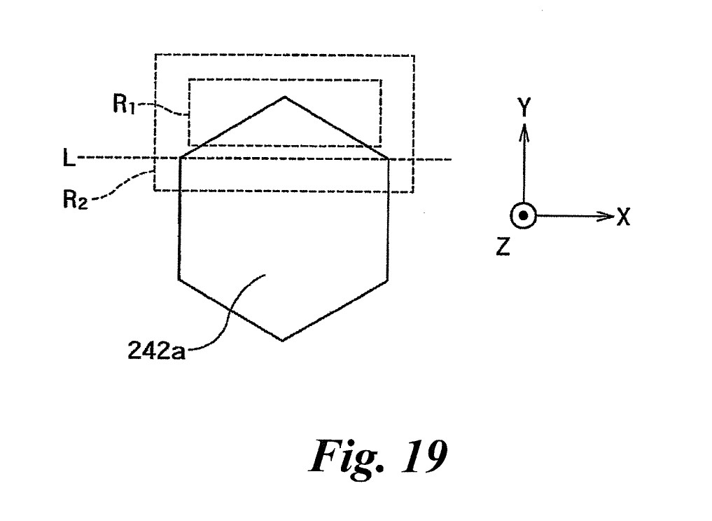

The opening part 242a of the supporting member 242 will be described in detail with reference to FIGS. 18A to 19.

FIGS. 18A to 18C illustrate beam structures.

The supporting member 242 of this embodiment has a honeycomb-type beam structure including, as shown in FIG. 18A, a first beam part B₁ parallel to the Y-direction, and a second beam part B₂ which is not parallel to the X-direction and the Y-direction. However, the supporting member 242 may have beam structures except for the above-described beam structure.

As shown in FIG. 18B, the supporting member 242 may have, e.g., a honeycomb-type beam structure including a first beam part B₁ in the X-direction, and a second beam part B₂ which is not parallel to the X-direction and the Y-direction.

As shown in FIG. 18C, the supporting member 242 may have a beam structure, e.g., including first and second beam parts B₁, B₂ which are not parallel to each other and are not perpendicular to each other. In FIG. 18C, the first and second beam parts B₁, B₂ are provided in a manner such that they are not both parallel to the X-direction and the Y-direction. The opening part 242a has a parallelogram shape.

In accordance with the beam structure shown in FIG. 18B or 18C, similarly to the beam structure shown in FIG. 18A, it becomes possible to allow improvement in the strength and enlightening of the supporting member 242 to be compatible. In this example, the opening part 242a of the supporting member 242 may have shapes except for the hexagonal shape, but may have, e.g., triangular shape, pentagonal shape or octagonal shape. The beam structure of the hexagonal opening part 242a may advantageously have the strength as compared to the beam structure of any other opening part 242a, with the same weight.

FIG. 19 illustrates the opening part 242a of the supporting member 242 from front.

A straight line L shown in FIG. 19 is a straight light connecting two adjacent vertices of the opening part 242a having hexagonal shape. The opening part 242a is divided into triangular part and hexagonal part by this line L.

Reference numeral R₁ indicates a region narrower than the above-mentioned triangular part within the opening part 242a. Reference numeral R₂ indicates a region broader than the above-mentioned triangular part within the opening part 242a.

In this embodiment, opening part 242a like a region R₂ is opened at the supporting member 242 as indicated by reference numeral P₃ in FIG. 11, but an opening part 242a like a region R₁ is not opened as indicated by reference numeral P₂. This is because the opening part 242a like the region R₁ exhibits less advantages/effects of enlightening of the supporting member 242.

As described above, in this embodiment, the cutting position of the straight line L is used as threshold value for determining as to whether or not opening part 242a is opened, but any cutting position may be used as threshold value.

### (5) Advantages/Effects of the Second Embodiment

Finally, the advantages/effects of the second embodiment will be described.

As described above, the supporting member 242 of this embodiment has a beam structure including first and second beam parts B₁, B₂ which are not parallel to each other and not perpendicular to each other. Thus, in accordance with this embodiment, similarly to the above-described first embodiment, it becomes possible to enhance rigidity of the supporting member 242 while enlightening the supporting member 242 by the beam structure.

This embodiment can be applied also to various electronic equipments except for the note-book type PC such as television receiver.

Although the first and second embodiments have been described above, these embodiments are only represented as examples, and should not limit the scope of the invention. These embodiments may be variously implemented with omissions, replacements, and/or changes and/or modifications, within the scope of the invention. These embodiments and such modifications will fall within the scope of the invention (Claims and its equivalents).

1. A television receiver comprising:
a first casing having a first opening part;
a second casing having a second opening part, and combined with the first casing;
a board positioned between the first casing and the second casing, the board having a third opening part communicating with the first opening part and the second opening part in a direction overlapping with the first casing and the second casing, the board further having a tubular surrounding part surrounding a periphery of the third opening part and projected toward an internal face of the second casing;
a projected part inserted from the internal face of the second casing toward the inside of the surrounding part;
a fixed member passing through the first opening part, the second opening part and the third opening part from the first casing side, and fixed at the projected part; and
a covering member provided on the first casing, and covering the first opening part.

2. The television receiver of claim 1,
wherein one face of the board is in contact with the internal face of the first casing.

3. The television receiver of claim 2,
wherein a wall of the first casing being in contact with the board has a fourth opening part, and
wherein an electronic component positioned within the fourth opening part is provided on the one face of the board to project therefrom.

4. The television receiver of claim 3,
wherein a second component is provided at the other face of the board opposite to the one face of the board to extend between the board and the internal face of the second casing, and
wherein a third electronic component is provided at a position out of the board to extend between the first casing and the second casing.

5. The television receiver of claim 3,
wherein the fourth opening part has a hexagonal shape, and
wherein the electronic component projected from the one face of the board is disposed along the hexagonal shape.

6. An electronic equipment comprising:
a first casing having a first opening part;
a second casing having a second opening part, and combined with the first casing;
a board positioned between the first casing and the second casing, the board having a third opening part communicating with the first opening part and the second opening part in a direction overlapping with the first casing and the second casing, the board further having a tubular surrounding part surrounding a periphery of the third opening part and projected toward an internal face of the second casing;
a projected part inserted from the internal face of the second casing toward the inside of the surrounding part;
a fixed member passing through the first opening part, the second opening part and the third opening part from the first casing side, and fixed at the projected part; and
a covering member provided on the first casing, and covering the first opening part.

7. The electronic equipment of claim 6,
wherein one face of the board is in contact with an internal face of the first casing.

8. The electronic equipment of claim 6,
wherein the covering member is configured to receive an external input.

9. An electronic equipment comprising:
a casing;
a board having an opening part and a projected part projected from a periphery of the opening part, at least a part of the board being accommodated within the casing;
a fixed part passing through the opening part and facing an internal face of the casing; and
a component passing through the opening part from the casing side to be fixed at the fixed part.

10. An electronic equipment comprising:
a first member;
a component having an opening part and an extended part extending between a periphery of the opening part and the first member, the component overlapping with the first member;
a second member overlapping with the component from the side opposite to the first member, at least part of the second member being in contact with a face of the component; and
a fixed part passing through the opening part and fixing the first member, the second member and the component.
